(19) United States
(12) Patent Application Publication
(10) Pub. No.: US 2003/0203627 A1
(43) Pub. Date: Oct. 30, 2003

(54) METHOD FOR FABRICATING THIN FILM TRANSISTOR

(76) Inventor: JIA-PANG PANG, TAICHUNG HSIEN (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,589

(22) Filed: Apr. 22, 2003

(30) Foreign Application Priority Data
Apr. 30, 2002 (TW) 91108946

(51) Int. Cl. H01L 21/302; H01L 21/461

(52) U.S. Cl. 438/689

(57) ABSTRACT

A method for fabricating thin film transistor (TFT). A substrate is provided, on which a gate, a gate insulating layer and a channel have been formed thereon. A conductive layer is formed on the channel, and a photoresist layer is formed on the conductive layer. The photoresist layer has an opening aligned over the gate. A wet etching step is performed using the photoresist layer as a mask, such that the conductive layer is partially removed with a thickness. A dry etching step is further performed to remove the residual thickness of the conductive layer and a thickness of the channel using the same photoresist layer as a mask to form a source/drain region.

### CROSS REFERENCE TO RELATED APPLICATIONS

This application claims the priority benefit of Taiwan application serial no.91108946, filed on Apr. 30, 2002.

### BACKGROUND OF INVENTION

1. Field of the Invention

The invention relates in general to a method for fabricating a liquid crystal display (LCD) device, and more particularly, to a method for fabricating a thin film transistor (TFT)

2. Description of the Related Art

Having the characteristics of low power consumption, thin type, light weight, and low driving voltage, liquid crystal displays have been broadly applied to medium or small sized portable televisions, video phones, camcorders, laptop computers, desktop computers and projection type televisions.

To comply with the trends of fabricating thin film transistor liquid crystal display with large dimension and high resolution, the fabrication process for thin film transistors becomes more and more delicate. That is, the wiring pattern of the thin film transistor array is smaller and smaller. Therefore, the thin film transistor array and wiring pattern, particularly the metal lines (data line and gate line) are normally formed by dry etching to achieve the objectives of dimension shrinkage and resolution enhancement.

FIGS. 1A to 1B are cross sectional views showing the conventional fabricating process of a thin film transistor, while FIG. 3 illustrates a top view of the thin film transistor formed by the conventional fabrication process.

Referring to FIG. 1A, a substrate 100 on which a gate 102, a gate insulating layer 104 and a channel layer 106 are formed is provided. A conductive layer 108 is formed on the channel layer 106. The conductive layer 108 includes a stacked layer of titanium/aluminum/titanium. A patterned photoresist layer 110 with an opening aligned over the gate 102 is formed on the conductive layer.

Referring to FIG. 1B, a dry etching step is performed using the photoresist layer 110 as a mask, so that the conductive layer 108 and a thickness of the channel layer 106 are removed to form an opening 112, while the remaining conductive layer at two sides of the opening 112 is the source/drain regions 118a and 118b.

A top view of the prior art thin film transistor using dry etching to remove the conductive layer and a portion of the channel layer is shown as FIG. 3. As the dry etching is an anisotropic etching step, the critical dimension of the channel length 112 between the source/drain regions 118a and 118b can be controlled. However, the dry etching machine has the disadvantages of low throughput and high cost. Further, the etching plasma easily damages the device during the dry etching process.

FIGS. 2A to 2B show another conventional fabrication process of a thin film transistor, and FIG. 4 illustrates a top view of the thin film transistor fabricated by the conventional process as shown in FIGS. 2A and 2B.

Referring to FIG. 2A, a substrate 200 is provided, on which a gate 202, a gate insulating layer 204 and a channel layer 206 are formed. A conductive layer 208 is formed on the channel layer 206. The conductive layer 208 includes a stacked layer of molybdenum/aluminum/molybdenum. A patterned photoresist layer 210 is formed on the conductive layer 208. The photoresist layer 210 has an opening 211 aligned over the gate 202.

Referring to FIG. 2B, a wet etching step is performed using the photoresist layer 210 as a mask to remove the conductive layer 208 and a thickness of the channel layer 206, so that an opening 212 is formed. The remaining conductive layer 208 at two sides of the opening 212 is the source/drain regions 218a and 218b.

As wet etching is an isotropic etching step, so that the width of the opening 212 is larger than the opening 211 of the photoresist layer 211. As a result, loss in critical dimension of the channel length between the source/drain regions 218a and 218b is caused. The thin film transistor formed by the prior art fabrication process that uses wet etching to remove the conductive layer and a part of the channel layer is shown in FIG. 4. As the opening formed by wet etching is typically larger, the channel length 220 between the source/drain regions 218a and 218b is difficult to control.

### SUMMARY OF INVENTION

The present invention provides a method for fabricating a thin film transistor to resolve the problems of low throughput, high cost and plasma damage of device for the prior art fabrication method.

The present invention also provides a method for fabricating a thin film transistor to resolve the problem of difficult to control the critical dimension of the channel length for the prior art fabrication method.

The present invention further provides a method for fabricating a substrate of a thin film transistor array, which combines dry etching and wet etching to overcome the drawbacks of the dry etching process and the wet etching process.

In the method of fabricating a thin film transistor provided by the present invention, a substrate on which a gate, a gate insulating layer and a channel layer are formed is provided. The conductive layer includes a stacked layer of molybdenum/aluminum/titanium. A patterned photoresist layer is formed on the conductive layer. A wet etching step is performed using the photoresist layer as a mask to remove only the molybdenum and aluminum layers of the conductive layer. Using the same photoresist layer as a mask, a dry etching step is further performed to remove the titanium layer of the conductive layer, such that a source/drain region is formed.

In the method of fabricating a substrate of a thin film transistor array, a first conductive layer is formed on a substrate, wherein the first conductive layer includes a gate and a gate line. A gate insulating layer is formed to cover the first conductive layer. A channel layer is formed on the gate insulating layer. A second conductive layer stacked by a molybdenum layer, an aluminum layer and a titanium layer is formed on the channel layer on the channel layer. A patterned photoresist layer is formed on the second conductive layer. A wet etching step is performed using the photoresist layer as a mask to remove the molybdenum layer and the aluminum layer. A dry etching step is further performed to remove the titanium layer, such that a source/drain region and a data wiring are formed.

The present invention uses a wet etching step to remove only the molybdenum layer and the aluminum layer of the second conductive layer. The titanium layer of the second conductive layer is removed by a dry etching step to control the critical dimension of the channel length, while the high throughput and low cost of the wet etching step are maintained.

Both the foregoing general description and the following detailed description are exemplary and explanatory only and are not restrictive of the invention, as claimed.

### BRIEF DESCRIPTION OF THE DRAWINGS

FIGS. 1A and 1B show a conventional fabrication method of a thin film transistor;

FIGS. 2A and 2B show another conventional method of a thin film transistor;

FIG. 3 shows a top view of the thin film transistor fabricated by the conventional method as shown in FIGS. 1A and 1B;

FIG. 4 shows a top view of the thin film transistor fabricated by the conventional method as shown in FIGS. 2A and 2B;

FIGS. 5A to 5C are cross sectional views of a method for fabricating a thin film transistor according to the present invention; and

FIG. 6 shows a top view of the thin film transistor fabricated by the conventional method as shown in FIGS. 5A to 5C.

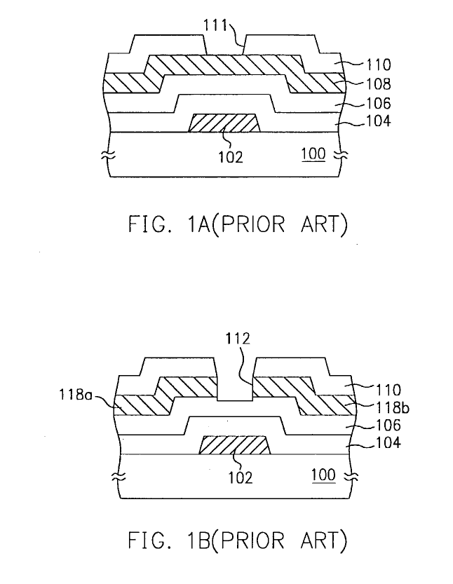

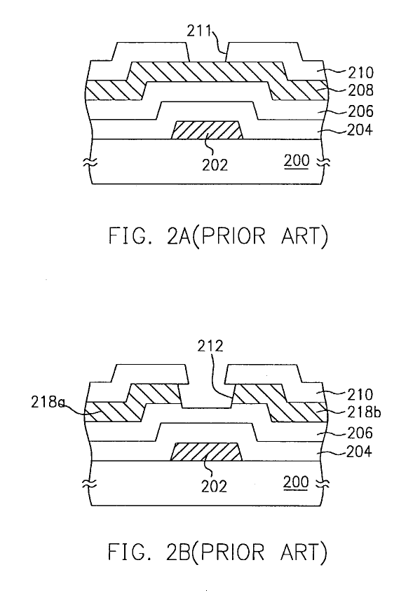

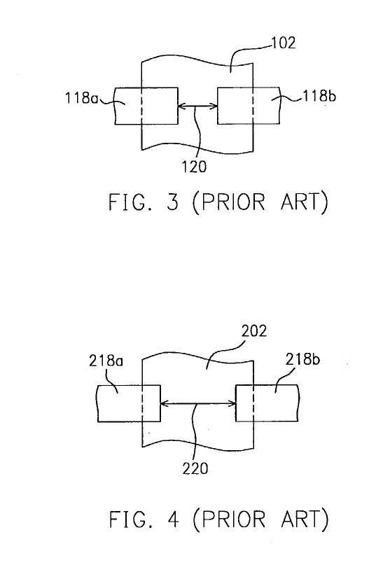

### DETAILED DESCRIPTION

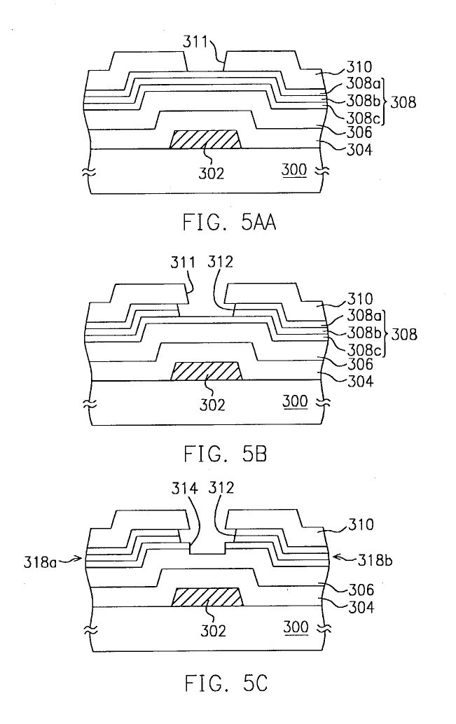

In FIGS. 5A to 5C, an embodiment of a method for fabricating a thin film transistor according to the present invention is shown.

Referring to FIG. 5A, a substrate 300 is provided. The substrate 300 includes a gate 302, a gate insulating layer 304, and a channel layer 305 formed thereon. The gate 302 includes a metal layer, the material for forming the gate insulating layer 304 includes silicon nitride, and the material for forming the channel layer 306 includes amorphous silicon, for example.

A conductive layer 308 is formed on the channel layer 306. The conductive layer 308 further comprises a first conductive layer 308a, a second conductive layer 308b and a third conductive layer 308c stacked together. Preferably, the first, second and third conductive layers 308a, 308b, and 308c include a molybdenum layer, an aluminum layer and a titanium layer, respectively. A patterned photoresist layer 310 is formed on the conductive layer 308. The patterned photoresist layer 310 has an opening 311 aligned over the gate 302 to expose a part of the conductive layer 308.

Referring to FIG. 5B, a wet etching step is performed to remove a part of the exposed conductive layer 308. In this embodiment, only the exposed first conductive layer 308a and the underlying second conductive layer 308b are removed in the wet etching step, such that an opening 312 is formed to expose a part of the third conductive layer 318c. The etching solution used in the wet etching step includes phosphoric acid, water, acetic acid, and nitric acid with a proportion of 65:25:5:5.

As the opening 312 is formed using isotropic wet etching, so that the width of the opening 312 is larger than the width of the opening 311.

Referring to FIG. 5C, a dry etching step is performed using the patterned photoresist layer 310 as a mask to remove the exposed third conductive layer 308c and a part of the underlying channel layer 306 with a predetermined thickness, so that an opening 314 is formed. The remaining conductive layer 308 at two sides of the openings 312 and 314 is thus the source/drain regions 318a and 318b. In the dry etching step, a mixed gas plasma of boron trichloride and chlorine is used to remove the third conductive layer 308c and the thickness of the channel layer 306.

As the third conductive layer 308c and the thickness of the channel layer 306 are removed using anisotropic dry etching, so that the opening 314 is not as wide as the opening 312. As a matter of fact, the width of the opening 314 is substantially equal to the width of the opening 311, so that the critical dimension of the channel length between the source/drain regions 318a and 318b can be controlled.

When the channel length is effectively reduced, the charging efficiency of the thin film transistor is enhanced. In contrast, when the channel length is increased, the dimension of the device has to be increased to maintain the original charging efficiency. However, increase of dimension cannot improve the resolution of the thin film transistor liquid crystal display. Therefore, the present invention uses wet etching to remove only a predetermined thickness of the conductive layer, and dry etching to remove the remaining thickness of the conductive layer, such that the high through put and low cost of wet etching are maintained, while the critical dimension of the channel length is controlled.

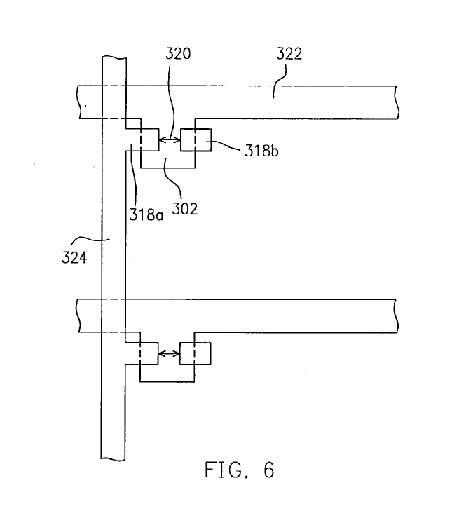

A top view of the thin film transistor array substrate formed by the fabrication method provided by the present invention is shown in FIG. 6. The gate line 322 can be formed simultaneously with the gate 302, while the data line 324 can be formed simultaneously with the source/drain regions 308.

The present invention combine wet etching and dry etching to pattern the conductive layer for forming the source/drain regions 318a and 318b, so that the channel length 320 is controlled by dry etching to prevent from forming the over-sized channel dimension. Further, as a predetermined thickness of the conductive layer is removed by wet etching, the drawbacks of high cost, low throughput and plasma damage caused by solely using dry etching are thus resolved.

In the above embodiment of the present invention, the portion of the conductive layer removed by wet etching includes the molybdenum layer and the aluminum layer, while the remaining titanium layer and a thickness of the channel layer are further removed by dry etching. Alternatively, the wet etching step may only remove the exposed molybdenum layer and a part of the underlying aluminum layer, and the remaining aluminum layer, the titanium layer and a part of the channel layer can then be removed by dry etching. Thereby, the critical dimension of the channel length can be controlled, while the high throughput and lost cost are maintained.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

1. A method for fabricating a thin film transistor, comprising:
providing a substrate, on which a gate, a gate insulating layer and a channel layer are formed;
forming a conductive layer stacked by a first conductive layer, a second conductive layer and a third conductive layer;
forming a patterned photoresist layer on the conductive layer, wherein the photoresist layer has an opening aligned over the gate;
performing a wet etching step with the photoresist layer as a mask to remove the first conductive layer and the second conductive layer; and
performing a dry etching step with the photoresist layer as a mask to remove the third conductive layer to form a source/drain region.

2. The method according to claim 1, wherein the dry etching step further removes a portion of the channel layer.

3. The method according to claim 1, the step of forming the conductive layer further comprising forming a molybdenum layer as the first conductive layer.

4. The method according to claim 1, the step of forming the conductive layer further comprising forming an aluminum layer as the second conductive layer.

5. The method according to claim 1, the step of forming the conductive layer further comprising forming a titanium layer as the third conductive layer.

6. The method according to claim 1, wherein the wet etching step further includes using a solution of phosphoric acid, water, acetic acid and nitric acid with the proportion of 65:25:5:5 as an etching solution.

7. The method according to claim 1, wherein the dry etching step further includes using a mixed gas of boron trichloride and chlorine as the etching plasma.

8. The method according to claim 1, wherein the gate includes a metal layer.

9. The method according to claim 1, wherein the gate insulating layer includes silicon nitride.

10. The method according to claim 1, wherein the channel layer includes amorphous silicon.

11. A method for fabricating a thin film transistor array substrate, comprising:
forming a first conductive layer on a substrate, wherein the first conductive layer comprises a gate and a gate line thereon;
forming a gate insulating layer to cover the first conductive layer;
forming a channel layer on the first conductive layer;
forming a second conductive layer, wherein the second conductive layer is formed by stacking a first metal layer, a second metal layer and a third metal layer together;
forming a patterned photoresist layer on the second conductive layer, wherein the photoresist layer has an opening aligned over the gate;
performing a wet etching step with the photoresist layer as a mask to remove the first metal layer and the second metal layer; and
performing a dry etching step to remove the third metal layer to form a source/drain region and a data line.

12. The method according to claim 11, wherein the dry etching step further removes a thickness of the channel layer.

13. The method according to claim 11, the step of forming the conductive layer further comprising forming a molybdenum layer as the first metal layer.

14. The method according to claim 11, the step of forming the conductive layer further comprising forming an aluminum layer as the second metal layer.

15. The method according to claim 11, the step of forming the conductive layer further comprising forming a titanium layer as the third metal layer.

16. The method according to claim 11, wherein the wet etching step includes using a solution of phosphoric acid, water, acetic acid and nitric acid with the proportion of 65:25:5:5 as an etching solution.

17. The method according to claim 11, wherein the dry etching step includes using a mixed gas of boron trichloride and chlorine as the etching plasma.

18. The method according to claim 11, wherein the gate includes a metal layer.

19. The method according to claim 11, wherein the gate insulating layer includes silicon nitride.

20. The method according to claim 1, wherein the channel layer includes amorphous silicon.

21. A method for fabricating a thin film transistor, comprising:
providing a substrate, on which a gate, a gate insulating layer and a channel layer are formed;
forming a conductive layer on the channel layer;
forming a photoresist layer on the conductive layer, the photoresist layer having an opening aligned over the gate;
using the photoresist layer as a mask to perform a wet etching step, so that the conductive layer is partially removed with a thickness; and
performing a dry etching step with the photoresist layer as a mask to remove the residual thickness of the conductive layer, so that a source/drain region is formed.

22. The method according to claim 21, wherein the dry etching step further removes a thickness of the channel layer.

23. The method according to claim 21, wherein the wet etching step includes using a solution of phosphoric acid, water, acetic acid and nitric acid with the proportion of 65:25:5:5 as an etching solution.

24. The method according to claim 21, wherein the dry etching step includes using a mixed gas of boron trichloride and chlorine as the etching plasma.

25. The method according to claim 21, wherein the gate includes a metal layer.

26. The method according to claim 21, wherein the gate insulating layer includes silicon nitride.

27. The method according to claim 21, wherein the channel layer includes amorphous silicon.

28. A method of fabricating a thin film transistor array substrate, comprising:
forming a first conductive layer on a substrate, the first conductive layer comprising a gate and a gate line;
forming a gate insulating layer to cover the first conductive layer;
forming a channel layer on the gate insulating layer;
forming a second conductive layer on the channel layer;
forming a photoresist layer on the second conductive layer, the photoresist layer having an opening aligned over the gate;
performing a wet etching using the photoresist layer as a mask, so that a thickness of the second conductive layer is removed; and
performing a dry etching step using the photoresist layer as a mask, so that the residual thickness of the second conductive layer is removed to form a drain/source region and a data line.

29. The method according to claim 28, wherein the dry etching step further removes a thickness of the channel layer.

30. The method according to claim 28, wherein the wet etching step includes using a solution of phosphoric acid, water, acetic acid and nitric acid with the proportion of 65:25:5:5 as an etching solution.

31. The method according to claim 28, wherein the dry etching step includes using a mixed gas of boron trichloride and chlorine as the etching plasma.

32. The method according to claim 28, wherein the gate includes a metal layer.

33. The method according to claim 28, wherein the gate insulating layer includes silicon nitride.

34. The method according to claim 28, wherein the channel layer includes amorphous silicon.
